(19) United States
(12) Patent Application Publication
(10) Pub. No.: US 2004/0001521 A1
(43) Pub. Date: Jan. 1, 2004

(54) Laser having active region formed above substrate

(76) Inventors: Ashish Tandon, Sunnyvale, CA (US); Ying-Lan Chang, Cupertino, CA (US); David Bour, Cupertino, CA (US)

Correspondence Address: AGILENT TECHNOLOGIES, INC., Intellectual Property Administration, Legal Department, DL429, P.O. Box 7599, Loveland, CO, 80537-0599, US

(21) Appl. No.: 10/185,268

(22) Filed: Jun. 27, 2002

(51) Int. Cl. H01S 5/00

(52) U.S. Cl. 372/45

(57) ABSTRACT

A semiconductor laser. The semiconductor laser has an indium-phosphide (InP) non-(100) substrate and an active region grown above the substrate. In so doing, embodiments of the present invention provide for the formation of a semiconductor laser with good morphology and low contamination while allowing the use of wide process windows. Opening the process window greatly simplifies the formation process, leads to more consistent results, and achieves better yields under mass production.

### TECHNICAL FIELD

Embodiments of the present invention relate to the field of semiconductor lasers. Specifically, embodiments of the present invention relate to a laser with an active region formed above an indium phosphide substrate whose surface is not oriented in a (100) plane and a method for forming such an active region.

### BACKGROUND ART

Vertical cavity surface emitting lasers (VCSELs), edge emitting lasers (EELs), and other lasers at 1.3 μm and 1.55 μm are of great interest for fiber optic communications due to the lower signal attenuation exhibited by existing fibers at these wavelengths. One of the material systems that is being investigated to achieve emitters at these wavelengths involves using aluminum-indium-gallium-arsenide (AlInGaAs) as the active region. However, conventional methods of forming such an active region have difficulty achieving good morphology and low contamination without resorting to very narrow process windows.

Conventional approaches pursued to attain AlInGaAs emitters at 1.3 μm or above have used indium-phosphide (InP) (100) substrates. The substrate orientations are defined according to an xyz coordinate system with the origin at the center of a crystalline lattice that forms the substrate. Thus, a surface of the (100) substrate has an ‘x’ displacement from the origin. Other substrates include (110), etc. InP substrates having a surface oriented in the (100) plane have been used because it has been traditional to use this plane for forming a semiconductor laser and substrates with a surface oriented in this plane are widely available. However, when forming an AlInAs surface on an InP substrate, indium rich dendrites may form. The dendrites substantially degrade the performance of the laser and tend to form if the distribution of indium and aluminum on the surface is non-uniform. A non-uniform distribution can easily occur using conventional methods because of the low surface mobility of aluminum atoms compared to indium atoms and because aluminum-arsenide (AlAs) is a more stable compound than indium-arsenide (InAs).

FIG. 1 illustrates results achieved for an aluminum-indium-arsenide (AlInAs) layer grown on an InP (100) substrate at 750 degrees Celsius and with a V/III ratio of approximately 50, for example, the ratio of periodic table group V elements to group III elements, using a metal-organic chemical vapor deposition (MOCVD) process. The surface picture 100 of an AlInAs eplilayer of FIG. 1 shows the formation of hundreds of dendrites 102 in an area of approximately 60 μm by 60 μm. Specifically, reference number 102 indicates several of the many dendrites 102 in the surface picture 100. The dendrites 102 are regions where the crystalline growth is undesirable for good active regions. The surface picture 100 also shows a smooth area (non-dendritic) as the dark area between dendrites.

While surface morphology is poor in FIG. 1, carbon and oxygen contamination is fairly low. FIG. 2 illustrates SIMS (Secondary Ion Mass Spectrometry) data 200 profiling aluminum, carbon, and oxygen in the aluminum-indium-arsenide (AlInAs) epilayer. The aluminum profile 202 is measured on the right axis. The concentration of the oxygen profile 204 and the carbon profile 206 are shown on the left axis. The contamination is kept relatively low by using a high V/III ratio, but at the expense of poor morphology. For example, the number of dendrites 102 may increase. This leads to bad quantum well interfaces.

FIG. 3 illustrates an AES (Auger Electron Spectroscopy) 300 of aluminum/indium ratio. Curve 302 shows the aluminum/indium ratio in the dendrite area 102. Curve 304 shows the aluminum/indium ratio in the smooth area 104. The aluminum/indium ratio in the dendrite area 102 is significantly lower than the aluminum/indium ratio in the planer area, indicating that the dendrites 102 are indium rich. Consequently, morphology is poor with this technique.

To counter the dendrite 102 problem, the temperature may be increased to enhance mobility of aluminum species. However, the growth temperature of AlInAs can only be increased to a certain degree without risking surface degradation. Furthermore, it is difficult to find a proper V/III ratio that will keep morphology good and contamination low. For example, a higher V/III ratio (e.g., 50), may keep the oxygen contamination low. Arsine and phosphine are viscous gases. A lowered V/III ratio therefore reduces the viscosity in the boundary layer and also lowers the surface coverage by As or P atoms. These effects help improve surface morphology by allowing better distribution of group III species both in the boundary layer and on the crystal growth interface. However, starting from a low V/III ratio (e.g., 10) even a small increase in the V/III ratio (e.g., to 15) may significantly degrade the surface morphology while only marginally reducing oxygen contamination. Consequently, conventional methods are constrained to a very narrow process window.

Furthermore, conventional processes are prone to spontaneous ordering. For example, when growing indium-aluminum-arsenide (InAlAs) the goal is to have the indium and aluminum randomly distributed along the group III sub-lattice. However, spontaneous ordering may occur in which a layer of the group III sub-lattice may be mostly aluminum or indium. Thus, the overall lattice may have thin layers of aluminum-arsenide (AlAs) and indium-arsenide (InAs) rather than layers of InAlAs.

Another problem faced when forming lasers with conventional techniques is achieving good doping characteristics. A contaminant such as oxygen may offset the effects of doping, and a contaminant such as carbon may act as a p-type dopant. Thus, contaminants need to be kept low to achieve good doping characteristics. Furthermore, the dopants may have different mobilities than the atoms that are to constitute the various layers of the laser. Consequently, the doping may be uneven using conventional techniques for the reasons discussed herein.

Thus, one problem with conventional methods for forming a semiconductor laser is that it is difficult to produce an active region with good morphology and low contamination without resorting to very narrow process windows. Another problem with conventional methods for forming semiconductor lasers is spontaneous ordering of the constituent elements. Another problem with conventional methods for forming semiconductor lasers is achieving good doping characteristics.

### DISCLOSURE OF THE INVENTION

The present invention pertains to a semiconductor laser. The semiconductor laser comprises an indium-phosphide (InP) non-(100) substrate and an active region grown above the substrate. In so doing, embodiments of the present invention provide for the formation of a semiconductor laser with good morphology and low contamination while allowing the use of wide process windows. Opening the process window greatly simplifies the formation process, leads to more consistent results, and achieves better yields under mass production.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a diagram of a surface picture of an AlInAs epilayer grown conventionally on InP (100) substrate using MOCVD.

FIG. 2 is a graph of SIMS data profiling aluminum, carbon, and oxygen in the AlInAs epilayer of the sample illustrated in FIG. 1.

FIG. 3 is a graph of AES data from the sample illustrated in FIG. 1.

FIG. 4 is a diagram of an InP non-(100) substrate that may be used by embodiments of the present invention to form a laser.

FIG. 5A and FIG. 5B illustrate schematics of a surface during an MOCVD process.

FIG. 6 illustrates how step velocity may be increased by using an InP non-(100) substrate, according to an embodiment of the present invention.

FIG. 7 illustrates an exemplary VCSEL that may be formed according to an embodiment of the present invention.

FIG. 8 illustrates steps of a process of forming a laser using an InP non-(100) substrate, according to an embodiment of the present invention.

FIG. 9 is a diagram of a surface picture of an AlInAs epilayer grown on an InP non-(100) substrate using the same growth conditions as the sample in FIG. 1, according to an embodiment of the present invention.

FIG. 10 is a graph of SIMS data profiling aluminum, carbon, and oxygen in the AlInAs epilayer of the sample illustrated in FIG. 9, according to an embodiment of the present invention.

FIG. 11 is a graph illustrating a comparison of photoluminescence of two samples grown on the same growth run using a conventional technique and a technique according to an embodiment of the present invention.

### DETAILED DESCRIPTION OF THE INVENTION

In the following detailed description of embodiments of the present invention, a semiconductor laser grown on an InP non-(100) substrate and method of forming the same, numerous specific details are set forth in order to provide a thorough understanding of embodiments of the present invention. However, embodiments of the present invention may be practiced without these specific details or by using alternative elements or methods. In other instances well known methods, procedures, components, and circuits have not been described in detail as not to unnecessarily obscure aspects of embodiments of the present invention.

Various embodiments of the present invention provide for a semiconductor laser that has good morphology and low contamination and may be formed under wide process windows. Embodiments of the present invention produce an active region of a laser with few contaminants such as oxygen and carbon. Embodiments of the present invention also have good doping characteristics. Furthermore, embodiments of the present invention eliminate spontaneous ordering of the laser's constituent elements.

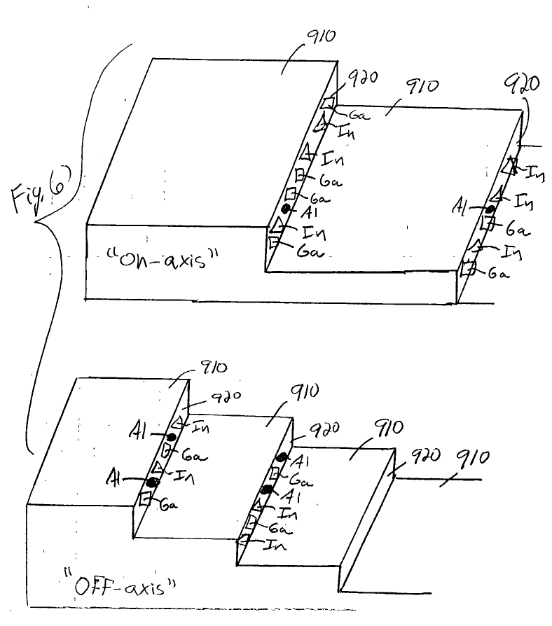

Referring now to FIG. 4, embodiments of the present invention use an InP substrate 800 having a surface off-axis from a (100) plane as a substrate for a semiconductor laser. For example, the InP substrate may be cut, grown, or formed off-axis from a (100) plane. For the purposes of this application, an InP substrate that cut, grown, or formed off-axis from a (100) plane may be referred to as an InP non-(100) substrate 800. This is in contrast to conventional techniques that may use an InP substrate that is cut, grown, or formed on-axis to a (100) plane, which may be referred to as an InP (100) substrate. In the embodiments of the present invention, the orientation of the surface of the non-(100) substrate 800 may be any orientation that is not a (100) plane. The surface of the InP non-(100) substrate 800 in FIG. 4 is shown with an angle 0 degrees from the (100) plane. The angle θ may be in any direction from the (100) plane. For example, the surface may be θ degrees towards another plane, such as a (110) plane, a (111)A plane, etc. However, in the embodiments of the present invention, the angle θ is not necessarily towards another plane.

Still referring to FIG. 4, embodiments of the present invention include using a substrate having a surface with an orientation other than a (100) plane, for example, a (110) plane, a (111)A plane, etc., as a semiconductor substrate. In some embodiments, the angle θ may be a slight deviation from the (100) orientation. For example, in one embodiment, θ may be on the order of greater than zero degrees to about fifteen degrees. However, embodiments of the present invention may have θ values outside of this range.

In one embodiment, the substrate material is InP, as that is a suitable material to lattice match with AlInGaAs regions of the laser. AlInGaAs may be used for the active regions because of its suitability of forming lasers that emit light at wavelengths of interest for fiber optic communications, for example 1.3 μm to 1.55 μm. However, embodiments of the present invention are not limited to fiber optic applications. Nor are embodiments of the present invention limited to these wavelengths. Furthermore, embodiments are not limited to AlInGaAs. Suitable group III elements may include, but are not limited to, aluminum, indium, and gallium. Suitable group V elements may include, but are not limited to, arsenic, phosphorus, antimony, and nitrogen. Embodiments of the present invention are well suited to fabricating active regions for lasers such as vertical cavity surface emitting lasers (VCSELs), edge emitting lasers, distributed feedback lasers, etc.

In one embodiment, using a substrate having a surface off-axis from a (100) plane reduces the problems related to the relatively low mobility of aluminum compared to indium. For example, dendrite formation such as indium rich dendrites will be lower, surface contaminants such as oxygen and carbon will be reduced, and surface morphology will be improved. This is accomplished with wider process windows and leads to a semiconductor laser with better photoluminescence properties than one formed under similar process conditions with a conventional InP (100) substrate.

As a further explanation of the benefits and advantages of embodiments of the present invention, FIG. 5A and FIG. 5B illustrate schematics of a surface during an MOCVD process. Referring to FIG. 5A, the surface comprises a series of atomically flat regions called terraces 910 separated by steps 920. MOCVD may also be known as OMCVD (Organo-metallic CVD), MOVPE (metal-organic vapor phase epitaxy), and OMVPE (Organo-metallic vapor phase epitaxy). Formation of the surface may be preceded by precursors, such as trimethyl gallium, trimethyl indium, trimethyl aluminum, and AsH₃ adhering to the surface. For clarity, only the aluminum, indium, and gallium are shown in FIG. 5A.

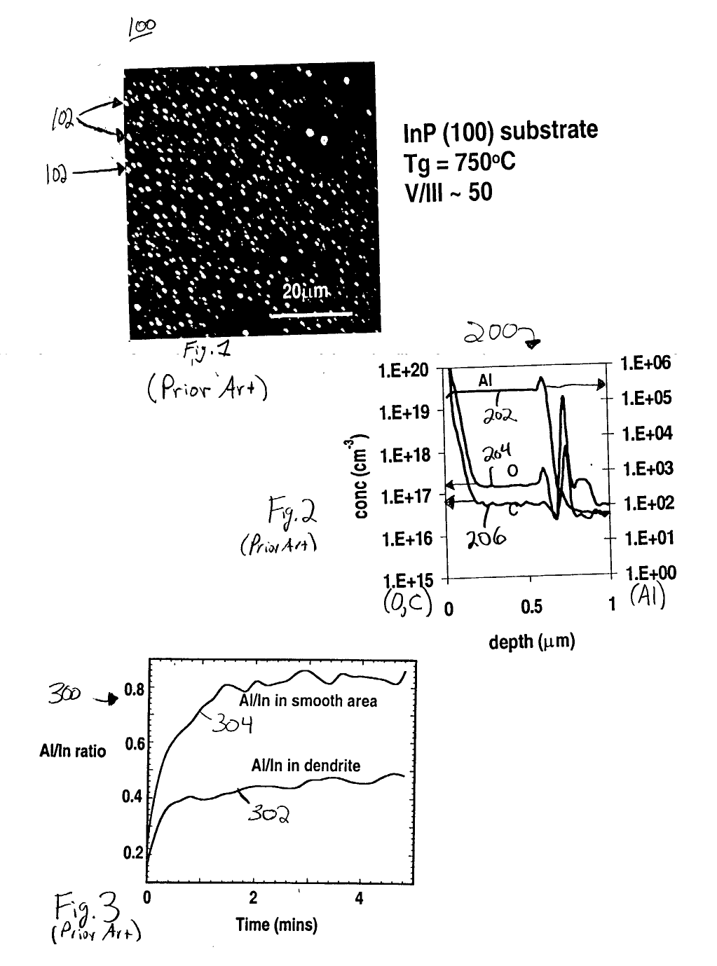

In FIG. 5A, a number of atoms that have yet to form bonds are shown on one terrace 910. Over time, they will diffuse across the surface until they bond. Referring to a later stage in the formation process as shown in FIG. 5B, bonding usually takes place at a step 920. However, sometimes adatoms 918, which may be detrimental to forming a good active region, bond away from a step 920. Because the indium atoms have greater mobility than the aluminum atoms, a given indium atom is likely to reach a step 920 before a given aluminum atom at the same distance from the step 920. Thus, indium atoms have a greater chance to bond at the steps 920. FIG. 5B shows a greater number of indium atoms than aluminum or gallium atoms have reached the step 920. Thus, the bonding pattern becomes non-random. When significant numbers of one element congregate in one area, a dendrite occurs such as, for example, dendrites 102 of Prior Art FIG. 1, and thereby leading to a poorly formed active region of a laser.

To alleviate formation problems, embodiments of the present invention increase step velocity by using an InP non-(100) substrate 800. For the purposes of the present application, step velocity may be defined as the inverse of the distance between steps on the surface under formation. In FIG. 6, the schematic labeled “on-axis” corresponds to a conventional (100) substrate. The schematic labeled “off-axis” corresponds to a non-(100) substrate 800, according to an embodiment of the present invention. The steps 920 are closer to one another in the “offaxis” schematic than in the “on-axis” schematic, for example they have a higher step velocity. Thus, atoms have an effectively smaller mean free path to a step 920 and hence to a likely bonding site. This may lead to fewer dendrites 102 and better surface morphology.

For example, the schematics in FIG. 6 may represent a case in which the goal is to have a lattice with equal amounts of indium, aluminum, and gallium. However, in the “on-axis” schematic more indium than aluminum atoms have bonded at the steps 920. In contrast, the ratio of indium to aluminum is about the same in the “off-axis” schematic. Moreover, because embodiments of the present invention reduce dendrite 102 formation, wider process windows may be used while forming a semiconductor laser with good morphology and low contamination. For example, a greater range in formation temperature, V/III ratio, and other process parameters may be used than conventional processes may use. As altering one of the process parameters tends to have both positive and negative impacts on the overall quality of the formed surface, having a greater process window allows greater freedom to select process parameters that have the greatest positive impact while minimizing negative impacts. While FIG. 6 illustrates an MOCVD process, embodiments of the present invention are not limited to MOCVD. For example, molecular beam epitaxy (MBE) may be used as well.

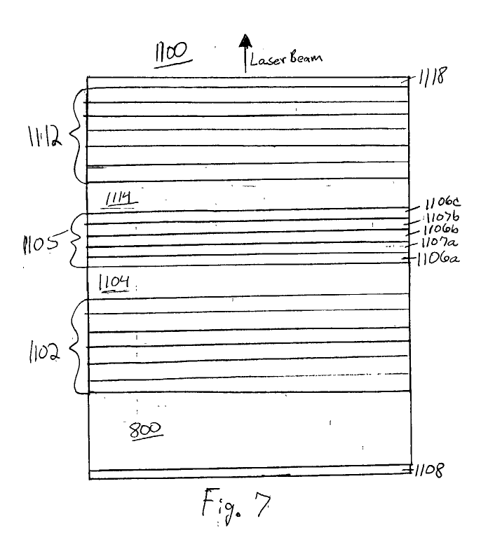

FIG. 7 illustrates an exemplary VCSEL 1100 that is formed in one embodiment of the present invention. The VCSEL 1100 comprises an InP non-(100) substrate 800. On top of the InP non-(100) substrate 800 are a number of layers comprising a mirror 1102. The layers may be lattice matched to the InP non-(100) substrate 800. On top of the mirror 1102 is a cladding layer 1104, which may be on the order of hundreds of nanometers thick. Above that is the active region 1105, which may comprise a number of quantum well layers 1106a-c and barrier layers 1107a-b. The thickness of the quantum well layers 1106 may be on the order of nanometers. The active region 1105 may comprise quantum wells configured with a direct energy band-gap in a range of approximately 0.8-0.95 eV, although the quantum wells may have other energy band-gaps. Another cladding layer 1114 and another mirror layer 1112 may reside on top of the active region 1105. The VCSEL 1100 may also have contact layers 1108, 1118 through which the laser beam is emitted. So as not to obscure the illustration, other layers commonly used in VCSELs have been omitted.

Embodiments of the present invention form an active region 1105 for any semiconductor laser for which an InP substrate is desired. Thus, embodiments of the present invention are not limited to the particular VCSEL 1100 illustrated in FIG. 7 or even to VCSELs. Thus, the active region 1105 may be formed in an edge emitting semiconductor laser, a distributed feedback laser, etc.

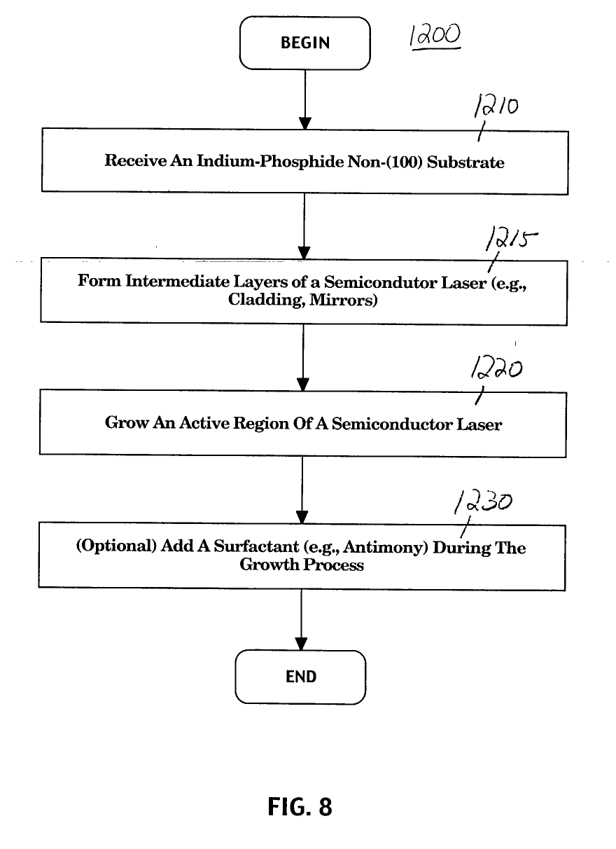

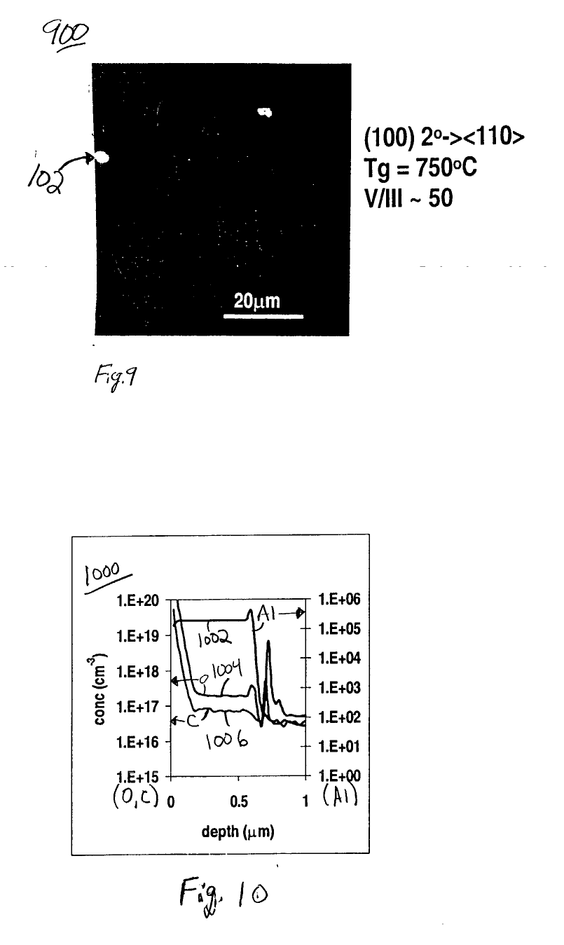

An embodiment of the present invention provides a process of forming a semiconductor laser, using an InP non-(100) substrate. Referring to process 1200 of FIG. 8 and additionally to FIG. 7, in step 1210 an InP non-(100) substrate 800 is received. While surfaces of such substrates are commonly oriented on-axis with respect to the (100) plane, it is within the skill of those in the art to form a surface of such a substrate off-axis to a (100) plane. Furthermore, the degree to which the surface of the substrate is off-axis may cover a wide range. Thus, suitable substrate surfaces may be fabricated with current technology.

In step 1215, one or more intermediate layers may be grown above the InP non-(100) substrate 800. For example, a mirror layer 1102 and a cladding layer 1104 may be grown above the InP non-(100) substrate 800. The intermediate layers may be, for example, AlInGaAs, although this is not required.

In step 1220, an active region 1105 of a semiconductor laser is formed from group V and III elements on the intermediate layers above the InP non-(100) substrate 800. The formation of the active region 1105 may comprise forming a plurality of layers of AlInGaAs of differing energies to form quantum well layers 1106 and barrier layers 1107 that are suitable for creating a laser of desired wavelength.

The growth process may optionally involve adding a surfactant such as Antimony. Adding a surfactant may allow elements with slower mobility than other elements, for example, aluminum, to reach the steps 920 of FIGS. 5A, 5B, and 6 in greater numbers. Thus, step 1230 may optionally be implemented in parallel with step 1220.

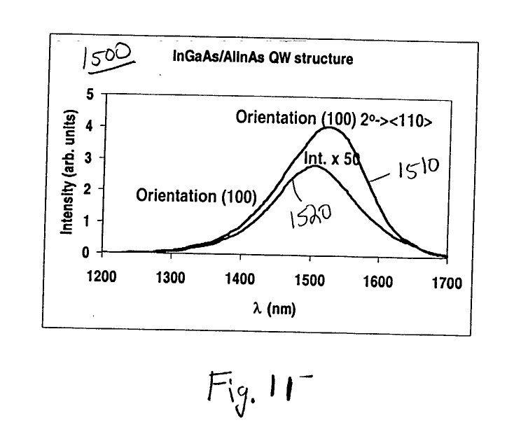

Embodiments of the present invention achieve good morphology and low contamination, while allowing for wide process windows. This is illustrated in FIG. 9 and FIG. 10, which show results of an AlInAs epilayer formed according to an embodiment of the present invention using an InP non-(100) substrate 800 during an MOCVD process at 750 degrees Celsius and a group V/III ratio of approximately 50. The AlInAs epilayer was grown during the same process run as the AlInAs epilayer grown on a conventional InP (100) substrate, whose results are shown in Prior Art FIGS. 1-3. The InP non-(100) substrate 800 had a surface two degrees towards the (110) plane. However, embodiments of the present invention are well suited to a substrate having a surface oriented towards other planes or even oriented in a direction that is not directly towards another plane.

The surface picture 900 of FIG. 9 illustrates that the epilayer grown on the InP non-(100) substrate has good morphology. In particular, the morphology is considerably better than that of Prior Art FIG. 1, in which a conventional InP (100) substrate was used. For example, Prior Art FIG. 1 shows hundreds of dendrites 102. However, FIG. 9 shows just two dendrites 102 in a window that covers approximately the same area.

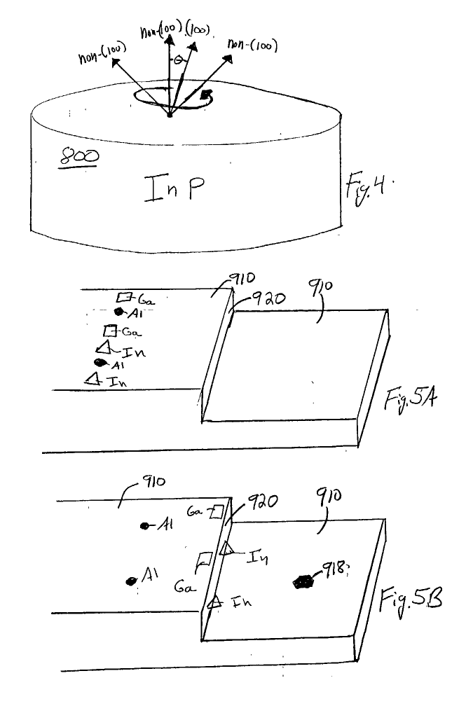

Moreover, the SIMS data 1000 in FIG. 10 show that the oxygen and carbon contamination is low. For example, the carbon profile 1002 shows a concentration that is essentially the same as that of the conventional process shown in Prior Art FIG. 2. The oxygen profile 1004 also shows a concentration that is essentially the same as that of the conventional process shown in Prior Art FIG. 2. Also, the aluminum profile 1002 matches that of the conventional process in Prior Art FIG. 2. Thus, embodiments of the present invention achieve good morphology and low contamination without resorting to very narrow process windows as must conventional methods.

Forming a surface with good morphology may be important for achieving a laser with high quantum efficiency. For example, if the edge of a region between a quantum well 1106 and a barrier 1107 is rough, the probability that an electron and hole will combine without giving off light is greater than if the region is smooth. Hence, the regions between layers should be smooth. Embodiments of the present invention produce are able to produce smoother edge regions and hence a superior laser, while using wider process windows than conventional methods.

The photoluminescence graph 1500 of FIG. 11 illustrates the superior results of an embodiment of the present invention over a conventional method under identical process conditions. Curve 1510 shows photoluminescence characteristics for an active region 1105 formed on an InP non-(100) substrate 800, according to an embodiment of the present invention. Curve 1520 shows photoluminescence characteristics for and an active region 1105 formed using a conventional InP (100) substrate. The two samples are the same ones whose results are shown in FIGS. 9 and 10, and Prior Art FIGS. 1-3 respectively. The InP non-(100) substrate 800 had a surface two degrees off-axis from a (100) plane and oriented towards a (110) plane. The active region 1105 is formed of InGaAs/AlInAs.

Still referring to FIG. 11, the InP non(100) curve 1510 shows the peak intensity of the sample formed on the InP non-(100) substrate 800 is substantially higher than the one formed on the conventional InP (100) substrate. Moreover, the active region 1105 formed on an InP non-(100) substrate 800 also shows an improvement in full width at half maximum. Further, the wavelength is suitable for optical communications.

Thus, embodiments of the present invention achieve superior results than conventional methods, while forming an active region 1105 of a laser under the same conditions. For example, the conventional results shown in Prior Art FIGS. 1-3 show an unacceptable number of dendrites 102, whereas the results of FIG. 9 according to an embodiment of the present invention show very few dendrites 102. Moreover, the photoluminescence properties of an embodiment of the present invention are superior to the conventional method. Therefore, embodiments of the present invention are able to use process parameters that are unavailable to conventional methods and still achieve good results. Opening the process window greatly simplifies the formation process, leads to more consistent results, and achieves better yields under mass production.

Also, embodiments of the present invention achieve good doping characteristics by limiting the amount of contaminants such as oxygen and carbon, while allowing wide process windows. Thus, a minimum of oxygen contamination is present to offset the effects of doping and a minimum of carbon is present to act as a p-type dopant. Furthermore, embodiments of the present invention spread desired doping material evenly throughout the laser by increasing the step velocity, as seen in FIG. 6 and described herein.

Additionally, embodiments of the present invention also minimize spontaneous ordering of the constituent elements of the laser, for example, aluminum, indium, and gallium. By embodiments of the present invention using an InP non(100) substrate to increase the step velocity during the formation process, the constituent elements are more likely to be randomly distributed within the sub-lattices. Thus, spontaneous ordering is minimized and laser quality is improved.

While the present invention has been described in particular embodiments, it should be appreciated that the present invention should not be construed as limited by such embodiments, but rather construed according to the below claims.

We claim:

1. A semiconductor laser comprising:
an indium-phosphide (InP) non-(100) substrate; and
an active region above said substrate.

2. The semiconductor laser of claim 1, wherein said active region comprises at least one group V element and at least one group III element.

3. The semiconductor laser of claim 2, wherein said at least one group III element is selected from the group consisting of aluminum, indium, and gallium.

4. The semiconductor laser of claim 2, wherein said at least one group V element is selected from the group consisting of arsenic, nitrogen, antimony, and phosphorous.

5. The semiconductor laser of claim 1, wherein said laser is a r vertical cavity surface emitting laser.

6. The semiconductor laser of claim 1, wherein said laser is an edge emitting laser.

7. The semiconductor laser of claim 1, wherein said laser is a distributed feedback laser.

8. The semiconductor laser of claim 1, wherein said laser is operable to emit light at a wavelength in the range of approximately 1.2 μm to 1.4 μm.

9. The semiconductor laser of claim 1, wherein said laser is operable to emit light at a wavelength of approximately 1.55 μm.

10. A semiconductor laser comprising:
an indium-phosphide (InP) substrate having a surface off-axis from a (100) plane;
one or more intermediate layers on top of said surface; and
an active region above said one or more intermediate layers, wherein said active region is operable to emit light at a wavelength greater than 1.2 μm.

11. The semiconductor laser of claim 10, wherein said substrate is off-axis from said (100) plane by greater than zero degrees to approximately 15 degrees.

12. The semiconductor laser of claim 10, wherein said active region comprises quantum wells configured with a direct energy band-gap in a range of approximately 0.8-0.95 eV.

13. The semiconductor laser of claim 10, wherein said active region is formed from AlInGaAs.

14. The semiconductor laser of claim 10, wherein said active region is operable to have a wavelength of approximately 1.55 μm.

15. A method of forming a semiconductor laser, comprising:
a) receiving an indium-phosphide (InP) non-(100) substrate; and
b) growing an active region of a laser above said substrate.

16. The method of claim 15, wherein said b) further comprises adding a surfactant during said growth.

17. The method of claim 16, wherein said surfactant is antimony.

18. The method of claim 15, wherein said b) comprises growing said active region using a metal organic chemical vapor deposition process.

19. The method of claim 15, wherein said b) comprises growing said active region using a molecular beam epitaxy process.

20. The method of claim 15, wherein said active region comprises AlInGaAs.
